(19) United States
(12) Patent Application Publication
(10) Pub. No.: US 2025/0374482 A1
(43) Pub. Date: Dec. 4, 2025

(54) SYSTEMS AND METHODS FOR COOLING OPERATING PLATFORMS OF AUTONOMOUS VEHICLES

(71) Applicant: Torc Robotics, Inc., Blacksburg, VA (US)

(72) Inventors: Nicholas Atanasov, Austin, TX (US); Dietrich Elmon Linde, Blacksburg, VA (US); Colin Butler, Salem, VA (US)

(21) Appl. No.: 18/731,197

(22) Filed: May 31, 2024

(51) Int. Cl. H05K 7/20; B60W 50/00; B60W 50/023

(52) U.S. Cl. CPC H05K 7/20281; B60W 50/023; B60W 50/0097; H05K 7/20872; B60W 2555/20

(57) ABSTRACT

A method and system for cooling an autonomy cooling system of a vehicle includes at least one fluid line defining a fluid passageway in thermal communication with at least one set of electronic control units (ECUs) of the autonomy computing system. A controller receives information relating to at least one of an environmental condition or an operating state of the vehicle, and determines a predicted computing load of an autonomy computing system of the vehicle based on the received information. The controller determines a predicted heat load generated by the autonomy computing system based on the predicted computing load of the autonomy computing system, and determines an operating parameter based on the predicted heat load. The system is operated based on the determined operating parameter to direct fluid through the fluid passageway and remove heat generated by the at least one set of ECUs.

### TECHNICAL FIELD

The field of the disclosure relates generally to cooling systems and, more specifically, cooling systems for autonomy computing systems of vehicles.

### BACKGROUND OF THE INVENTION

Autonomous vehicles, semi-autonomous vehicles, non-autonomous vehicles, and smart vehicles may include an autonomy computing system and sensors that provide information during operation of the vehicles. For example, the sensors may include radio detection and ranging (RADAR) sensors, light detection and ranging (LiDAR) sensors, cameras, acoustic sensors, temperature sensors, or inertial navigation system (INS), and be configured to collect information regarding the environment while the vehicle is traveling. The autonomy computing system receives the information and determines operating parameters for safely operating the vehicle based on the information from the sensors. The autonomy computing system may at least partly operate the vehicle based on the information received from the sensors and the determined operating parameters.

During operation of the vehicle, the autonomy computing system generates heat that must be managed and/or removed from the system to ensure that the system operates reliably and to increase longevity of the system. In addition, the vehicle may experience conditions that can increase the temperature and/or processing demands of the autonomy computing system and potentially lead to overheating of the autonomy computing system. Overheating can hinder operation of the autonomy computing system and the vehicle and may even lead to failure of the autonomy computing system.

Accordingly, there is a need for a cooling system that efficiently cools an autonomy computing system of a vehicle and reduces the risk of failure of the autonomy computing system.

This section is intended to introduce the reader to various aspects of art that may be related to various aspects of the present disclosure described or claimed below. This description is believed to be helpful in providing the reader with background information to facilitate a better understanding of the various aspects of the present disclosure. Accordingly, it should be understood that these statements are to be read in this light and not as admissions of prior art.

### SUMMARY OF THE INVENTION

In one aspect, a method for cooling an autonomy computing system of a vehicle includes receiving, at a controller, information relating to at least one of an environmental condition or an operating state of the vehicle, and determining a predicted computing load of the autonomy computing system of the vehicle based on the received information. The autonomy computing system includes at least one set of electronic control units (ECUs) that are configured to operate the vehicle. The method also includes determining a predicted heat load generated by the autonomy computing system based on the predicted computing load of the autonomy computing system, and determining an operating parameter of a cooling system based on the predicted heat load. The cooling system including at least one fluid line defining a fluid passageway in thermal communication with the autonomy computing system of the vehicle. The method further includes operating the cooling system based on the determined operating parameter to direct fluid through the fluid passageway and remove heat generated by the at least one set of ECUs.

In another aspect, a system for cooling an autonomy computing system of a vehicle includes at least one fluid line defining a fluid passageway in thermal communication with at least one set of electronic control units (ECUs) of the autonomy computing system of the vehicle. The autonomy computing system is configured to operate the vehicle. The system also includes a controller and at least one heat exchanger connected to the at least one fluid line. The controller is configured to receive information relating to at least one of an environmental condition or an operating state of the vehicle, determine a predicted computing load of the autonomy computing system of the vehicle based on the received information, and determine a predicted heat load generated by the autonomy computing system based on the predicted computing load of the autonomy computing system. The controller is also configured to determine an operating parameter of the system based on the predicted heat load and operate the system based on the determined operating parameter to direct fluid through the fluid passageway and remove heat generated by the at least one set of ECUs.

In yet another aspect, a vehicle includes an autonomy computing system including at least one set of electronic control units (ECUs), and at least one sensor communicatively coupled to the at least one set of ECUs. The at least one set of ECUs is configured to process information provided by the at least one sensor and operate the vehicle. The vehicle includes a cooling system including at least one fluid line in thermal communication with the autonomy computing system and defining a fluid passageway for fluid to receive heat generated by the autonomy computing system. The vehicle also includes a controller configured to receive information relating to at least one of an environmental condition or an operating state of the vehicle, determine a predicted computing load of the autonomy computing system of the vehicle based on the received information, and determine a predicted heat load generated by the autonomy computing system based on the predicted computing load of the autonomy computing system. The controller is configured to determine an operating parameter of the cooling system based on the predicted heat load and operate the cooling system based on the determined operating parameter to direct fluid through the fluid passageway and remove heat generated by the autonomy computing system.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1 is a schematic diagram of a vehicle;

FIG. 2 is a block diagram of a vehicle;

FIG. 3 is a schematic block diagram of a system for cooling an autonomy computing system of the vehicle;

FIG. 4 is a flow chart of an example method of cooling the autonomy cooling system of the vehicle; and

FIG. 5 is a block diagram of an example computing device.

Corresponding reference characters indicate corresponding parts throughout the several views of the drawings. Although specific features of various examples may be shown in some drawings and not in others, this is for convenience only. Any feature of any drawing may be referenced or claimed in combination with any feature of any other drawing.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure.

An autonomous vehicle: An autonomous vehicle is a vehicle that is able to operate itself to perform various operations such as controlling or regulating acceleration, braking, or steering wheel positioning, without any human intervention. An autonomous vehicle has an autonomy level of level-4 or level-5 recognized by National Highway Traffic Safety Administration (NHTSA).

A semi-autonomous vehicle: A semi-autonomous vehicle is a vehicle that is able to perform some of the driving related operations such as keeping the vehicle in lane or parking the vehicle without human intervention. A semi-autonomous vehicle has an autonomy level of level-1, level-2, or level-3 recognized by NHTSA.

A non-autonomous vehicle: A non-autonomous vehicle is a vehicle that is driven by a human driver. A non-autonomous vehicle is neither an autonomous vehicle nor a semi-autonomous vehicle. A non-autonomous vehicle has an autonomy level of level-0 recognized by NHTSA.

A smart vehicle: A smart vehicle is a vehicle installed with on-board computing devices, one or more sensors, one or more controllers, or one or more internet-of-things (IoT) devices which enables the vehicle to receive or transmit data to another vehicle or a server.

Embodiments of the present application include systems and methods for cooling a vehicle. For example, during operation of the vehicle, an autonomy computing system of the vehicle generates heat. The systems and methods described herein provide efficient management of the heat generated by the autonomy computing system without negatively impacting operation of the vehicle. In addition, the systems and methods facilitate continued operation of the vehicle even if at least one system of the vehicle is in a failure state.

For example, embodiments of the present application include a cooling system including a fluid line in thermal communication with an autonomy computing system and configured to remove heat generated by the autonomy computing system. A controller is configured to receive information relating to an environmental condition or an operating state of the vehicle and determine a predicted computing load of the autonomy computing system of the vehicle based on the received information. Also, the controller is configured to determine a predicted heat load generated by the autonomy computing system based on the predicted computing load of the autonomy computing system. The controller is configured to determine an operating parameter based on the predicted heat load and operate the cooling system to direct fluid through the fluid passageway and remove heat generated by the autonomy computing system. In some embodiments, the controller is configured to identify failure states of one or more systems of the vehicle and operate the cooling system to accommodate the failure state. For example, the cooling system includes a plurality of independent cooling loops and the controller operates the cooling loops to provide cooling to a portion of the autonomy computing system that performs a function corresponding to a function of a system in a failure state. As a result, the cooling system facilitates continued operation of the vehicle even when one or more systems of the vehicle are in a failure state.

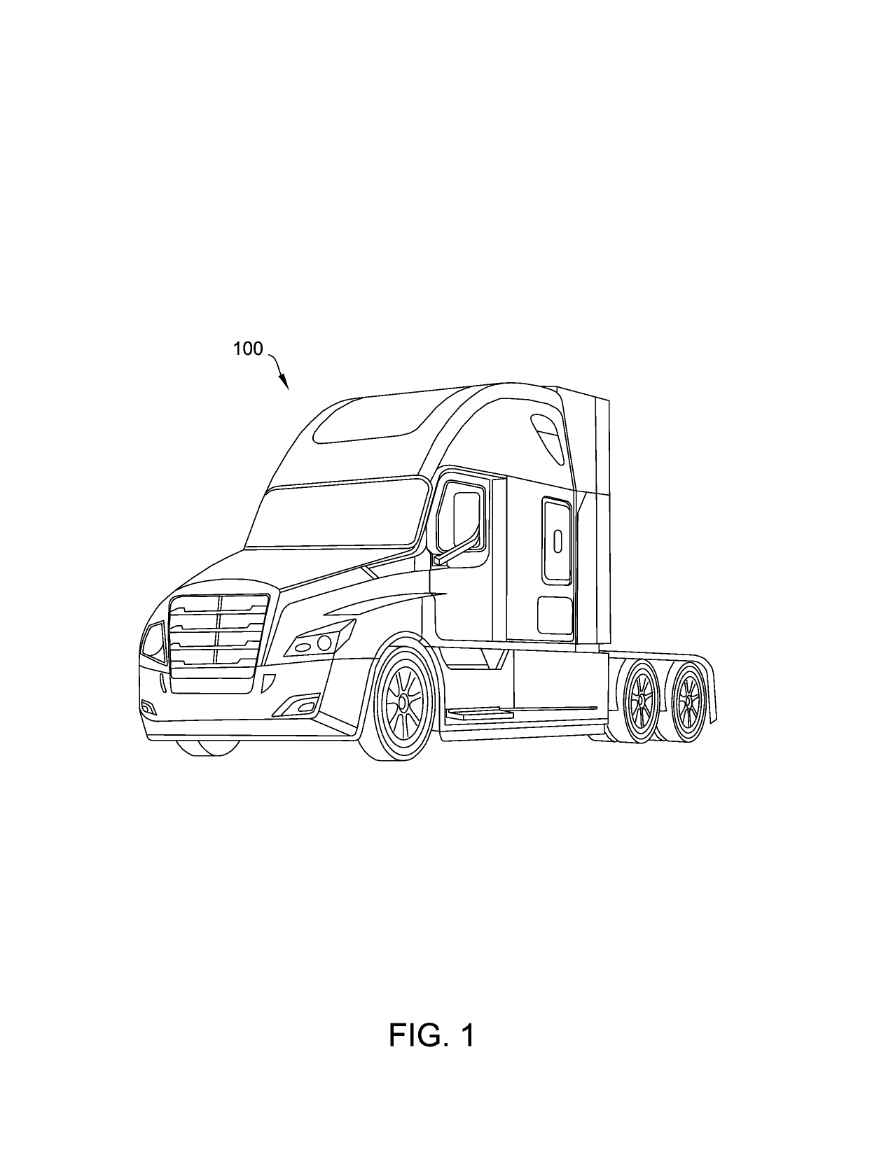

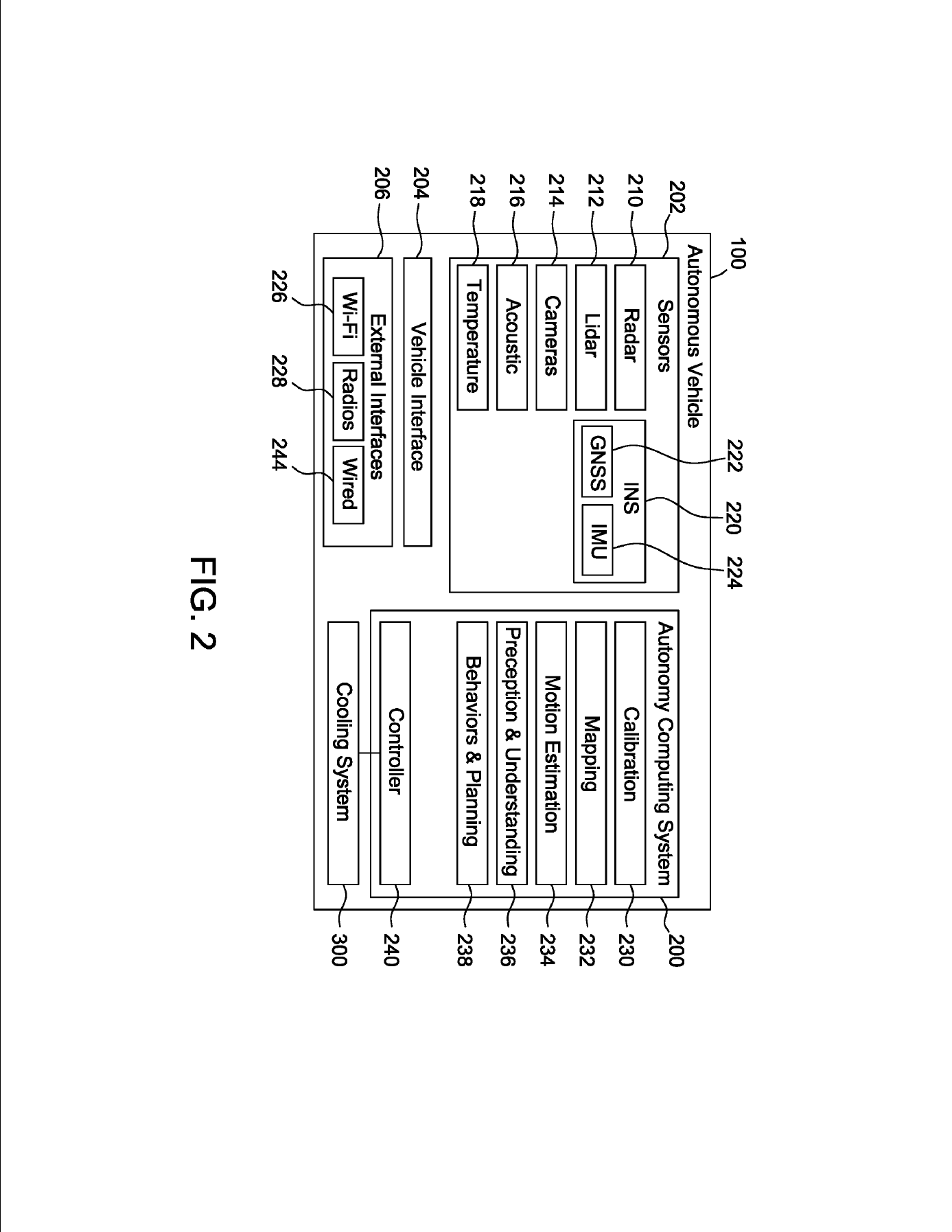

FIG. 1 is a schematic diagram of a vehicle 100. FIG. 2 is a block diagram of vehicle 100. In the example embodiment, vehicle 100 includes autonomy computing system 200, sensors 202, a vehicle interface 204, and external interfaces 206. For example, vehicle 100 may be an autonomous vehicle, a semi-autonomous vehicle, a non-autonomous vehicle, or a smart vehicle. In the example embodiment, vehicle 100 is an autonomous vehicle and includes autonomy computing system 200, sensors 202, a vehicle interface 204, and external interfaces 206. As described in further detail below, a cooling system 300 is configured to manage heat generated by autonomy computing system 200 and/or other components of vehicle 100.

In the example embodiment, sensors 202 may include various sensors such as, for example, radio detection and ranging (RADAR) sensors 210, light detection and ranging (LiDAR) sensors 212, cameras 214, acoustic sensors 216, temperature sensors 218, or inertial navigation system (INS) 220, which may include one or more global navigation satellite system (GNSS) receivers 222 and one or more inertial measurement units (IMU) 224. Other sensors 202 not shown in FIG. 2 may include, for example, acoustic (e.g., ultrasound), internal vehicle sensors, meteorological sensors, or other types of sensors. Sensors 202 generate respective output signals based on detected physical conditions of vehicle 100 and its proximity. As described in further detail below, these signals may be used by autonomy computing system 200 to determine how to control operation of vehicle 100.

Cameras 214 are configured to capture images of the environment surrounding vehicle 100 in any aspect or field of view (FOV). The FOV can have any angle or aspect such that images of the areas ahead of, to the side, behind, above, or below vehicle 100 may be captured. In some embodiments, the FOV may be limited to particular areas around vehicle 100 (e.g., forward of vehicle 100, to the sides of vehicle 100, etc.) or may surround 360 degrees of vehicle 100. In some embodiments, vehicle 100 includes multiple cameras 214, and the images from each of the multiple cameras 214 may be stitched or combined to generate a visual representation of the multiple cameras’ FOVs, which may be used to, for example, generate a bird’s eye view of the environment surrounding vehicle 100. In some embodiments, the image data generated by cameras 214 may be sent to autonomy computing system 200 or other aspects of vehicle 100, and this image data may include vehicle 100 or a generated representation of vehicle 100. In some embodiments, one or more systems or components of autonomy computing system 200 may overlay labels to the features depicted in the image data, such as on a raster layer or other semantic layer of a high-definition (HD) map.

LiDAR sensors 212 generally include a laser generator and a detector that send and receive a LiDAR signal such that LiDAR point clouds (or “LiDAR images”) of the areas ahead of, to the side, behind, above, or below vehicle 100 can be captured and represented in the LiDAR point clouds. Radar sensors 210 may include short-range RADAR (SRR), mid-range RADAR (MRR), long-range RADAR (LRR), or ground-penetrating RADAR (GPR). One or more sensors may emit radio waves, and a processor may process received reflected data (e.g., raw radar sensor data) from the emitted radio waves. In some embodiments, the system inputs from cameras 214, radar sensors 210, or LiDAR sensors 212 may be fused or used in combination to determine conditions (e.g., locations of other objects) around vehicle 100.

GNSS receiver 222 is positioned on vehicle 100 and may be configured to determine a location of vehicle 100, which it may embody as GNSS data, as described herein. GNSS receiver 222 may be configured to receive one or more signals from a global navigation satellite system (e.g., Global Positioning System (GPS) constellation) to localize vehicle 100 via geolocation. In some embodiments, GNSS receiver 222 may provide an input to or be configured to interact with, update, or otherwise utilize one or more digital maps, such as an HD map (e.g., in a raster layer or other semantic map). In some embodiments, GNSS receiver 222 may provide direct velocity measurement via inspection of the Doppler effect on the signal carrier wave. Multiple GNSS receivers 222 may also provide direct measurements of the orientation of vehicle 100. For example, with two GNSS receivers 222, two attitude angles (e.g., roll and yaw) may be measured or determined. In some embodiments, vehicle 100 is configured to receive updates from an external network (e.g., a cellular network). The updates may include one or more of position data (e.g., serving as an alternative or supplement to GNSS data), speed/direction data, orientation or attitude data, traffic data, weather data, or other types of data about vehicle 100 and its environment.

IMU 224 is a micro-electrical-mechanical (MEMS) device that measures and reports one or more features regarding the motion of vehicle 100, although other implementations are contemplated, such as mechanical, fiber-optic gyro (FOG), or FOG-on-chip (SiFOG) devices. IMU 224 may measure an acceleration, angular rate, and or an orientation of vehicle 100 or one or more of its individual components using a combination of accelerometers, gyroscopes, or magnetometers. IMU 224 may detect linear acceleration using one or more accelerometers and rotational rate using one or more gyroscopes and attitude information from one or more magnetometers. In some embodiments, IMU 224 may be communicatively coupled to one or more other systems, for example, GNSS receiver 222 and may provide input to and receive output from GNSS receiver 222 such that autonomy computing system 200 is able to determine the motive characteristics (acceleration, speed/direction, orientation/attitude, etc.) of vehicle 100.

In the example embodiment, autonomy computing system 200 employs vehicle interface 204 to send commands to the various aspects of vehicle 100 that actually control the motion of vehicle 100 (e.g., engine, throttle, steering wheel, brakes, etc.) and to receive input data from one or more sensors 202 (e.g., internal sensors). External interfaces 206 are configured to enable vehicle 100 to communicate with an external network via, for example, a wired or wireless connection, such as Wi-Fi 226 or other radios 228. In embodiments including a wireless connection, the connection may be a wireless communication signal (e.g., Wi-Fi, cellular, LTE, 5g, Bluetooth, etc.).

In some embodiments, external interfaces 206 may be configured to communicate with an external network via a wired connection 244, such as, for example, during testing of vehicle 100 or when downloading mission data after completion of a trip. The connection(s) may be used to download and install various lines of code in the form of digital files (e.g., HD maps), executable programs (e.g., navigation programs), and other computer-readable code that may be used by vehicle 100 to navigate or otherwise operate, either autonomously or semi-autonomously. The digital files, executable programs, and other computer readable code may be stored locally or remotely and may be routinely updated (e.g., automatically or manually) via external interfaces 206 or updated on demand. In some embodiments, vehicle 100 may deploy with all of the data it needs to complete a mission (e.g., perception, localization, and mission planning) and may not utilize a wireless connection or other connection while underway.

In the example embodiment, autonomy computing system 200 is implemented by one or more processors and memory devices of vehicle 100. Autonomy computing system 200 includes modules, which may be hardware components (e.g., processors or other circuits) or software components (e.g., computer applications or processes executable by autonomy computing system 200), configured to generate outputs, such as control signals, based on inputs received from, for example, sensors 202. These modules may include, for example, a calibration module 230, a mapping module 232, a motion estimation module 234, a perception and understanding module 236, a behaviors and planning module 238, a control module or controller 240. These modules may be implemented in dedicated hardware such as, for example, an application specific integrated circuit (ASIC), field programmable gate array (FPGA), or microprocessor, or implemented as executable software modules, or firmware, written to memory and executed on one or more processors onboard vehicle 100.

Autonomy computing system 200 of vehicle 100 may be completely autonomous (fully autonomous) or semi-autonomous. In one example, autonomy computing system 200 can operate under Level 5 autonomy (e.g., full driving automation), Level 4 autonomy (e.g., high driving automation), or Level 3 autonomy (e.g., conditional driving automation). As used herein the term “autonomous” includes both fully autonomous and semi-autonomous.

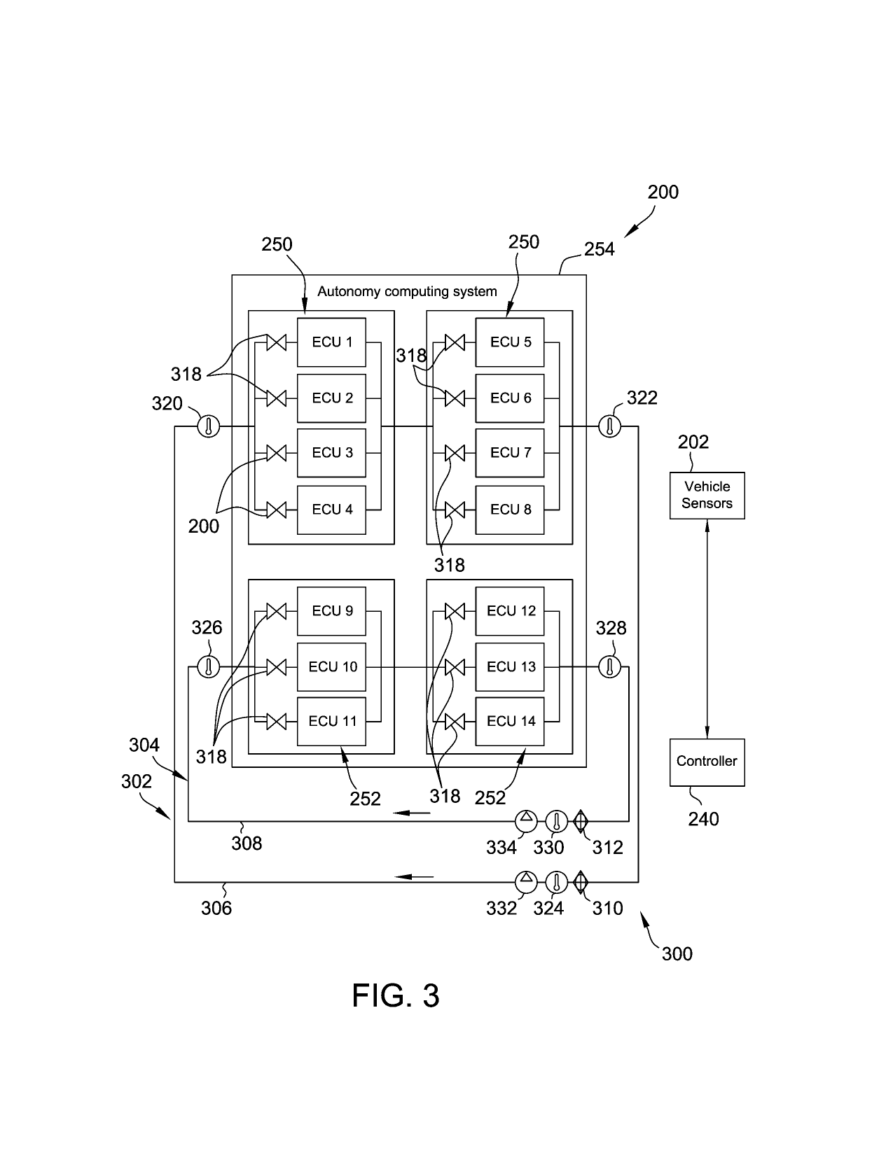

FIG. 3 is a schematic block diagram of cooling system 300 of vehicle 100. Cooling system 300 includes a first cooling loop 302 and a second cooling loop 304. First cooling loop 302 and second cooling loop 304 provide an increased capacity for managing heat generated by autonomy computing system 200. For example, first cooling loop 302 or second cooling loop 304 may provide cooling to components of autonomy computing system 200 and facilitate vehicle continuing traveling and/or making a safety maneuver even if a portion of cooling system 300 is inoperable.

In the example embodiment, autonomy computing system 200 includes a first set of electronic control units (ECUs) 250 and a second set of ECUs 252. For example, first set of ECUs 250 includes ECUs 1-8. Second set of ECUs includes ECUs 9-14. ECUs 250, 252 may each include a processor, circuits, memory, and communication interfaces. For example, ECUs 250, 252 may receive and process signals from sensors 202 and/or implement modules 230, 232, 234, 236, 238, 240 (shown in FIG. 2) to operate vehicle 100 (shown in FIG. 1). Accordingly, first set of ECUs 250 and second set of ECUs 252 generate heat during operation of vehicle 100 (shown in FIG. 1).

Cooling system 300 is configured to remove or manage heat generated by ECUs 250, 252 of autonomy computing system 200. For example, first cooling loop 302 of cooling system 300 includes a first fluid line 306 in thermal communication with first set of ECUs 250 of autonomy computing system 200 and configured to remove heat generated by first set of ECUs 250 of autonomy computing system 200. Second cooling loop 304 of cooling system 300 includes a second fluid line 308 in thermal communication with second set of ECUs 252 of autonomy computing system 200 and configured to remove heat generated by second set of ECUs 252 of autonomy computing system 200. In the example embodiment, first cooling loop 302 and second cooling loop 304 are arranged to operate independently and provide cooling to separate portions of autonomy computing system 200.

Fluid lines 306, 308 each define a fluid passageway for fluid to flow through. For example, fluid lines 306, 308 may include pipes, flexible tubing, channels, manifolds, joints, and/or any suitable components defining a fluid passageway. Fluid lines 306, 308 are arranged to receive any suitable fluid including, for example and without limitation, liquid, gas, or combinations of liquid and gas. For example, the fluid in fluid lines 306, 308 receives heat generated by autonomy computing system 200 and is channeled through the fluid passageway to components configured to manage the heat. In some embodiments, the fluid includes glycol or another suitable refrigerant material to facilitate the heat transfer and cooling process. The fluid in fluid lines 306, 308 is returned to autonomy computing system 200 to remove additional heat after flowing through the respective cooling loop 306, 308 and/or interacting with a component configured to remove heat from the fluid.

Cooling system 300 includes one or more components coupled to fluid lines 306, 308 and configured to remove heat from the fluid flowing through the fluid passageways defined by fluid lines 306, 308. For example, cooling system 300 includes a first heat exchanger 310 coupled to fluid line 306 and configured to facilitate heat transfer from the fluid in the fluid passageway of fluid line 306 to an ambient environment when the fluid is directed to heat exchanger 310. Cooling system 300 includes a second heat exchanger 312 coupled to second fluid line 308 and configured to facilitate heat transfer from the fluid in the fluid passageway of second fluid line 308 to an ambient environment when the fluid is directed to heat exchanger 312. For example, heat exchangers 310, 312 receive the heated fluid in the respective fluid passageways and direct the heated fluid through a coil which interacts with forced air. The forced air removes heat from the fluid in the fluid passageway and distributes the heat to the ambient environment. In some embodiments, cooling system 300 includes at least one liquid-to-liquid heat exchanger coupled to first fluid line 306 and/or second fluid line 308. For example, the liquid-to-liquid heat exchanger may interact with the fluid in the fluid passageway and exchanges heat between liquids.

Cooling system 300 includes one or more components along fluid lines 306, 308 to facilitate fluid flow and/or provide information relating to the flow of fluid through fluid line 306. For example, cooling system 300 includes valves 318 coupled to fluid lines 306, 308. Valves 318 are configured to direct or regulate fluid flow through the fluid passageways. In the example, embodiment, valves 318 are used to direct the cooling fluid towards selected ECUs of the first set of ECUs 250 and/or the second set of ECUs during operation of cooling system 300.

In addition, cooling system 300 includes at least one pump 332 coupled to first fluid line 306 and configured to cause the fluid to flow through the fluid passageway defined by first fluid line 306. Cooling system 300 includes at least one second pump 334 coupled to second fluid line 308 and configured to cause the fluid to flow through the fluid passageway defined by second fluid line 308. For example, pumps 332, 334 may be configured to direct the fluid towards heat exchanger 310, 312 and/or valves 318.

Also, cooling system 300 includes a first temperature sensor 320 coupled to first fluid line 306 upstream of autonomy computing system 200, a second temperature sensor 322 coupled to first fluid line 306 downstream of autonomy computing system 200, and/or a third temperature sensor 324 coupled to first fluid line 306 downstream of heat exchanger 310. Cooling system 300 includes a fourth temperature sensor 326 coupled to second fluid line 308 upstream of autonomy computing system 200, a fifth temperature sensor 328 coupled to second fluid line 308 downstream of autonomy computing system 200, and/or a sixth temperature sensor 330 coupled to second fluid line 308 downstream of heat exchanger 310. Temperature sensors 320, 322, 324, 326, 328, 330 are arranged to measure a temperature of the fluid in fluid lines 306, 308.

In some embodiments, cooling system 300 includes a compressor. The compressor may be dedicated only to cooling system 300 and not connected to external components. For example, the compressor may be coupled to a power source (e.g., an alternator) on vehicle 100 (shown in FIG. 1) and receive power only from the power source. Alternatively, the compressor may be dual purpose and be connected to other components of vehicle 100 such as an air conditioning system.

Controller 240 is communicatively coupled to and configured to operate valves 318, first heat exchanger 310, second heat exchanger 312, and/or any other components of cooling system 300. For example, controller 240 is configured to actuate valves 318 to selectively direct the fluid in the fluid passageways toward portions of autonomy computing system 200. In addition, controller 240 is configured to operate heat exchangers 310, 312 to manage heat carried by the fluid in fluid lines 306, 308.

Controller 240 is configured to receive information relating to an operating condition of vehicle 100 from sensors 202 and/or modules 230, 232, 234, 236, 238 (shown in FIG. 2) and operate cooling system 300 based on the received information. For example, in some embodiments, the operating condition includes a temperature of the ambient environment around vehicle 100 and/or a temperature associated with autonomy computing system 200 and/or cooling system 300. For example, controller 240 may be configured to receive a temperature of the ambient environment around vehicle 100 from temperature sensor 218 shown in FIG. 2 and/or temperatures of fluid in the fluid passageway from temperature sensors 320, 322, 324, 326, 328, 330. In further embodiments, the information relates to a traffic pattern associated with a location and/or a predicted path of vehicle 100 (shown in FIG. 1).

Controller 240 is configured to determine a predicted computing load of autonomy computing system 200 based on the received information. For example, controller 240 calculates a processing load for each ECU of first set of ECUs 250 and/or second set of ECUs based on anticipated inputs from sensors 202 during operation of vehicle 100. The anticipated inputs are calculated based on operating conditions of the vehicle including, for example and without limitation, weather, traffic patterns, road conditions, and/or an operating state of vehicle 100. Controller 240 calculates the expected impact of each condition and associates the expected impact with one or more sensors that provide signals to the first set of ECUs 250 and second set of ECUs. Based on the anticipated inputs received from the sensors, controller 240 determines a processing load for each ECU of first set of ECUs 250 and second set of ECUs 252.

In addition, controller 240 is configured to determine a predicted heat load generated by autonomy computing system 200 based on the predicted computing load of autonomy computing system 200. For example, in some embodiments, controller 240 compares the predicted computing load for each ECU of first set of ECUs 250 and second set of ECUs 252 to a lookup table stored on a memory and retrieves a predicted heat load associated with the predicted computing load. In further embodiments, controller 240 inputs the predicted computing load of each ECU of first set of ECUs 250 and second set of ECUs 252 into an algorithm and the algorithm outputs a predicted heat load. In some embodiments, controller 240 adjusts the predicted heat load based on an environmental condition such as a temperature associated with autonomy computing system 200.

Controller 240 is configured to determine an operating parameter of cooling system 300 based on the predicted heat load and operate cooling system 300 based on the determined operating parameter to direct fluid through the fluid passageway and remove heat generated by first set of ECUs 250 and second set of ECUs. For example, controller 240 operates at least one valve 318 coupled to fluid line 306 and/or fluid line 308 to selectively direct the fluid in the fluid passageway toward at least one ECU of first set of ECUs 250 and/or second set of ECUs based on the determined operating parameter. For example, controller 240 is configured to determine an amount of the predicted computing load that is associated with the at least one ECU of first set of ECUs 250 and/or second set of ECUs, and operate cooling system 300 to account for the predicted computing load that is associated with the at least one ECU of first set of ECUs 250 and/or second set of ECUs. In the example embodiment, controller 240 is configured to operate cooling system 300 to proactively provide cooling for components of ECU based on the predicted computing load and predicted heat load. Accordingly, cooling system 300 provides cooling before or when an actual heat load occurs instead of reacting after heat is already generated or to an increase in temperature. As a result, cooling system 300 more efficiently manages heat generated by autonomy computing system 200 and reduces risk of failure due to overheating.

In addition, controller 240 and cooling system 300 facilitate vehicle 100 continuing to operate or performing an emergency maneuver even if one or more components of vehicle 100 fail. For example, controller 240 is configured to determine a failure state of at least one first ECU of first set of ECUs 250 and/or second set of ECUs 252 and operate cooling system 300 to accommodate the failure state. For example, controller 240 to identify that a first ECU of first set of ECUs 250 or second set of ECUs 252 is in a failure state or at risk for failure by comparing a temperature associated with the first ECU to a threshold temperature. The first ECU is identified as in a failure state or at risk for failure when the temperature associated with the first ECU is equal to or greater than the threshold temperature. Controller 240 may cause the first ECU to deactivate when the first ECU reaches the failure state. In some embodiments, controller 240 monitors the temperature of the first ECU and allows the first ECU to continue to operate until the first ECU reaches a second threshold temperature or until the first ECU reaches an inoperable state. When controller 240 identifies the first ECU is in a failure state or at risk for failure, controller 240 is configured to identify a second ECU of first set of ECUs 250 or second set of ECUs 252 that performs a function that corresponds to a function of the first ECU. For example, the first ECU and the second ECU may receive and process signals from different sensors that provide information relating to the same or overlapping fields of view. Autonomy computing system 200 is operated to accommodate the failure state of the first ECU by relying on the second ECU for designated functions associated with the first ECU. Controller 240 operates cooling system 300 to provide additional cooling for any increase in the predicted computing load or the predicted heat load of the second ECU preforming the designated functions. In some embodiments, controller 240 operates valves 318 to divert cooling fluid to the second ECU.

Referring to FIGS. 2 and 3, to assemble cooling system 300, fluid lines 306, 308 are positioned in thermal communication with autonomy computing system 200 such that fluid in the fluid passageway is configured to remove heat generated by autonomy computing system 200. For example, first fluid line 306 is coupled to first set of ECUs 250 of autonomy computing system 200 and configured to remove heat generated by one or more ECUs of first set of ECUs 250. Second fluid line 308 is coupled to second set of ECUs 252 of autonomy computing system 200 and configured to remove heat generated by one or more ECUs of second set of ECUs 252. In the example embodiment, first set of ECUs 250 are arranged in two groups and each group includes four ECUs. Second set of ECUs 252 are arranged in two groups and each group includes three ECUs. In alternative embodiments, autonomy computing system 200 may include any number of ECUs arranged in sets and/or groups.

Each ECU of first set of ECUs 250 is connected to a separate branch of first fluid line 306. Each ECU of second set of ECUs 252 is connected to a separate branch of second fluid line 308. Each branch of first fluid line 306 and second fluid line 308 includes one valve 318 that is configured to regulate fluid flow to individual ECUs. Accordingly, cooling system 300 is configured to provide independent control of cooling to individual ECUs in first set of ECUs 250 and second set of ECUs 252.

In the example embodiment, first set of ECUs 250 and second set of ECUs 252 of autonomy computing system 200 are enclosed within a housing 254. Housing 254 supports first set of ECUs 250 and second set of ECUs 252 and protects autonomy computing system 200 from the environment and from damage from objects. Fluid lines 306, 308 extend into and out of housing 254 through openings in housing 254 and are coupled to first set of ECUs 250 and second set of ECUs 252 within housing 254.

First heat exchanger 310 is coupled to first fluid line 306 downstream of autonomy computing system 200 to facilitate heat transfer from fluid in the fluid passageway to the ambient environment when the fluid is directed to heat exchanger 310 and heat exchanger 310 is in an ON state. Also, second heat exchanger 312 is coupled to second fluid line 308 downstream of autonomy computing system 200 to facilitate heat transfer from fluid in the fluid passageway to the ambient environment when the fluid is directed to heat exchanger 312 and heat exchanger 312 is in an ON state.

In the example, first pump 332 is coupled to first fluid line 306 to direct the fluid toward heat exchanger 310. Second pump 334 is coupled to second fluid line 308 to direct fluid toward heat exchanger 312. Pumps 332, 334 may be any suitable pump(s) and are arranged to cause fluid to flow within first fluid line 306 and/or second fluid line 308. In addition, valves 318 are connected to first fluid line 306 and to second fluid line 308 and arranged to selectively direct the fluid in the fluid passageway to ECUs of first set of ECUs 250 or second set of ECUs 252.

Controller 240 is communicatively coupled to valve 318, heat exchanger 310, and heat exchanger 312. Controller 240 is configured to receive information relating to an operating parameter of vehicle 100 and, based on the received information, operate cooling system 300 to remove heat from autonomy computing system 200.

During operation, controller 240 receives information from vehicle sensors 202, modules 230, 232, 234, 236, 238, and/or temperature sensors 320, 322, 324, 326, 328, 330. Based on the received information, controller 240 determines a predicted heat load generated by autonomy computing system 200 and operates cooling system 300 to remove the predicted heat load from autonomy computing system 200. For example, controller 240 operates pumps 332, 334 to direct fluid through first cooling loop 302 and second cooling loop 304 when the predicted heat load is above a threshold level.

Pumps 332, 334 cause the fluid to flow through the respective fluid passageway toward autonomy computing system 200. For example, fluid in first cooling loop 302 flows toward first set of ECUs 250 and fluid in second cooling loop 304 flows toward second set of ECUs 252. The fluid in first cooling loop 302 and second cooling loop 304 flows into separate branches of fluid lines 306, 308 in fluid communication with individual ECUs. Controller 240 operates valves 318 coupled to each branch to selectively direct cooling fluid to individual ECUs. The cooling fluid in the branches interacts with individual ECUs of autonomy computing system 200 and receives heat generated by autonomy computing system 200. The branches may merge between and after interacting with groups of ECUs 250, 252 to mix the cooling fluid and facilitate even and efficient cooling of autonomy computing system 200.

After flowing through autonomy computing system 200, the fluid in first cooling loop 302 and second cooling loop 304 converges within a common line. After the fluids mix, the common line separates into first fluid line 306 and second fluid line 308. Fluid in first fluid line 306 flows towards heat exchanger 310. Fluid in second fluid line 308 flows towards heat exchanger 312. Heat exchangers 310, 312 remove heat from the fluids. Pump 332 connected to first fluid line 306 directs the fluid in first cooling loop 302 back towards autonomy computing system 200. Pump 334 connected to second fluid line 308 directs the fluid in second cooling loop 304 back towards autonomy computing system 200.

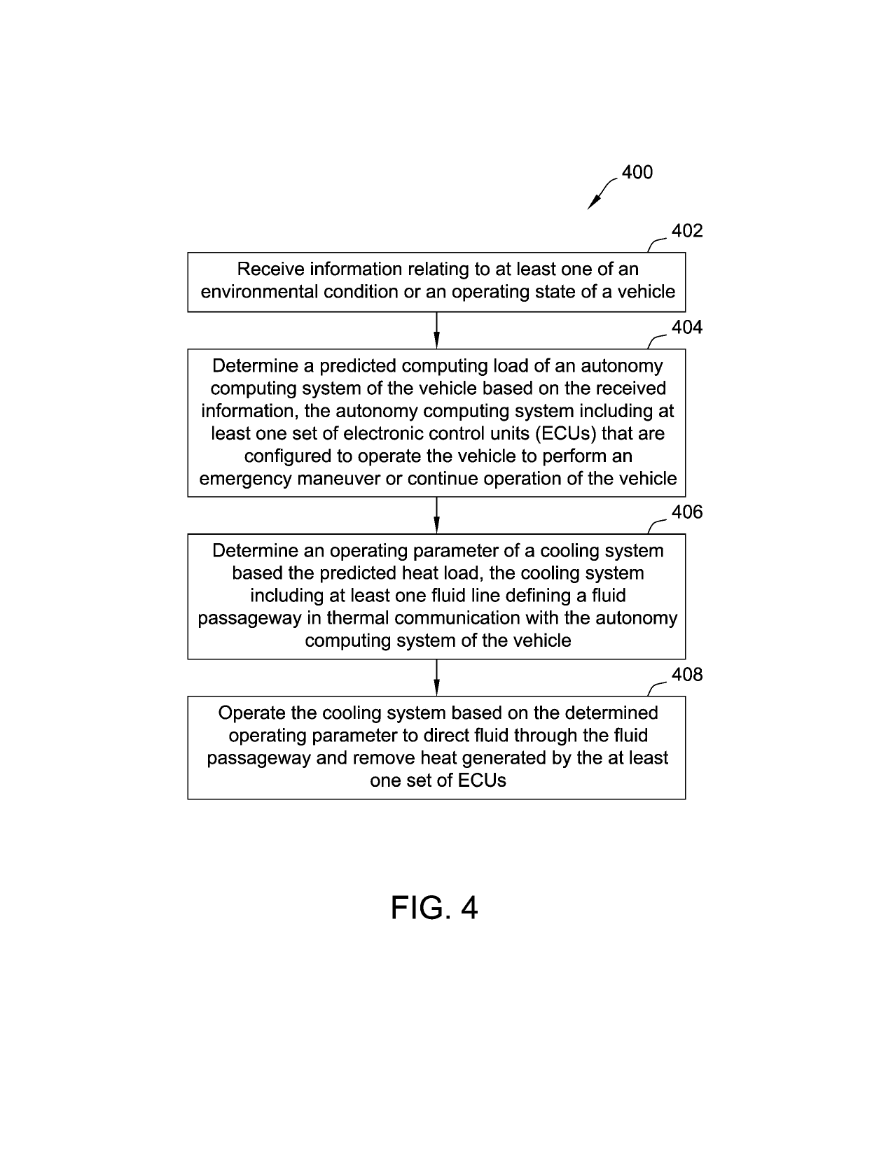

FIG. 4 is a flow chart of an example method 400 of cooling autonomy computing system 200 of vehicle 100 using cooling system 300 (shown in FIG. 3). Referring to FIGS. 2-4, during operation of cooling system 300, controller 240 receives 402 information relating to at least one of an environmental condition or an operating state of vehicle 100. For example, controller 240 receives information from sensors 202 and/or temperature sensors 320, 322, 324. Controller 240 receives information continually during operation of cooling system 300 and may change operating parameters (e.g., an operating state of cooling system 300) at any time based on the received information.

Controller 240 determines 404 a predicted computing load of autonomy computing system 200 of vehicle 100 based on the received information. For example, the received information may include a temperature of an ambient environment around vehicle 100, a temperature associated with the at least one set of ECUs 250, 252, a speed of vehicle 100, a location of vehicle 100, and/or a traffic pattern associated with a location and predicted path of vehicle 100. Controller 240 determines the predicted computing load for each set of ECUs 250, 252 by determining the signals that will be sent from associated sensors 202 based on the received information. For example, sensors 202 may provide signals or information to ECUs 250, 252 that require a larger computing load when traffic is present around vehicle 100 than when no traffic is around vehicle 100. In addition, weather, a speed of vehicle 100, or other factors may all increase the computing load for ECUs 250, 252.

Controller 240 determines 406 a predicted heat load generated by autonomy computing system 200 based on the predicted computing load of autonomy computing system 200. For example, controller 240 determines 406 a predicted heat load for each ECU 250, 252 based on the associated predicted computing load. In some embodiments, controller 240 determines a total predicted heat load for first set of ECUs 250 and/or second set of ECUs 252

Controller 240 determines 408 an operating parameter of cooling system 300 based on the predicted heat load and operates 410 cooling system 300 based on the determined operating parameter to direct fluid through the fluid passageway and remove heat generated by ECUs 250, 252 of autonomy computing system 200. For example, controller 240 operates cooling system 300 to provide independent cooling for first set of ECUs 250 and/or second set of ECUs 252 using cooling loops 302 and 304. For example, controller 240 operates one or more valves 318 coupled to first fluid line 306 and/or second fluid line 308 to selectively direct the fluid in the fluid passageway toward at least one ECU of first set of ECUs 250 and/or second set of ECUs 252 based on the determined operating parameter. In some embodiments, cooling system 300 has different operating states and controller 240 selects an operating state for cooling system 300 based on the predicted heat load. For example, if the predicted heat load is below a threshold level, cooling system 300 may be operated according to a level 1 operating state in which cooling fluid is circulated but heat exchangers 310, 312 may not be active. If the predicted heat load is equal to or above the threshold level, cooling system 300 may be operated according to a level 2 operating state in which heat exchangers 310, 312 are operated to remove heat from the fluid.

In some embodiments, autonomy computing system 200 is operated to accommodate the failure state of a first ECU by relying on the functions of a second ECU. For example, controller 240 determines a failure state of a first ECU and identifies a second ECU that performs a function that corresponds to a function of the first ECU. Controller 240 then operates vehicle 100 to rely on the second ECU for the designated function and perform an emergency maneuver or continue operation. Controller 240 operates cooling system 300 to provide cooling to the second ECU when vehicle 100 performs the emergency maneuver or continues operation.

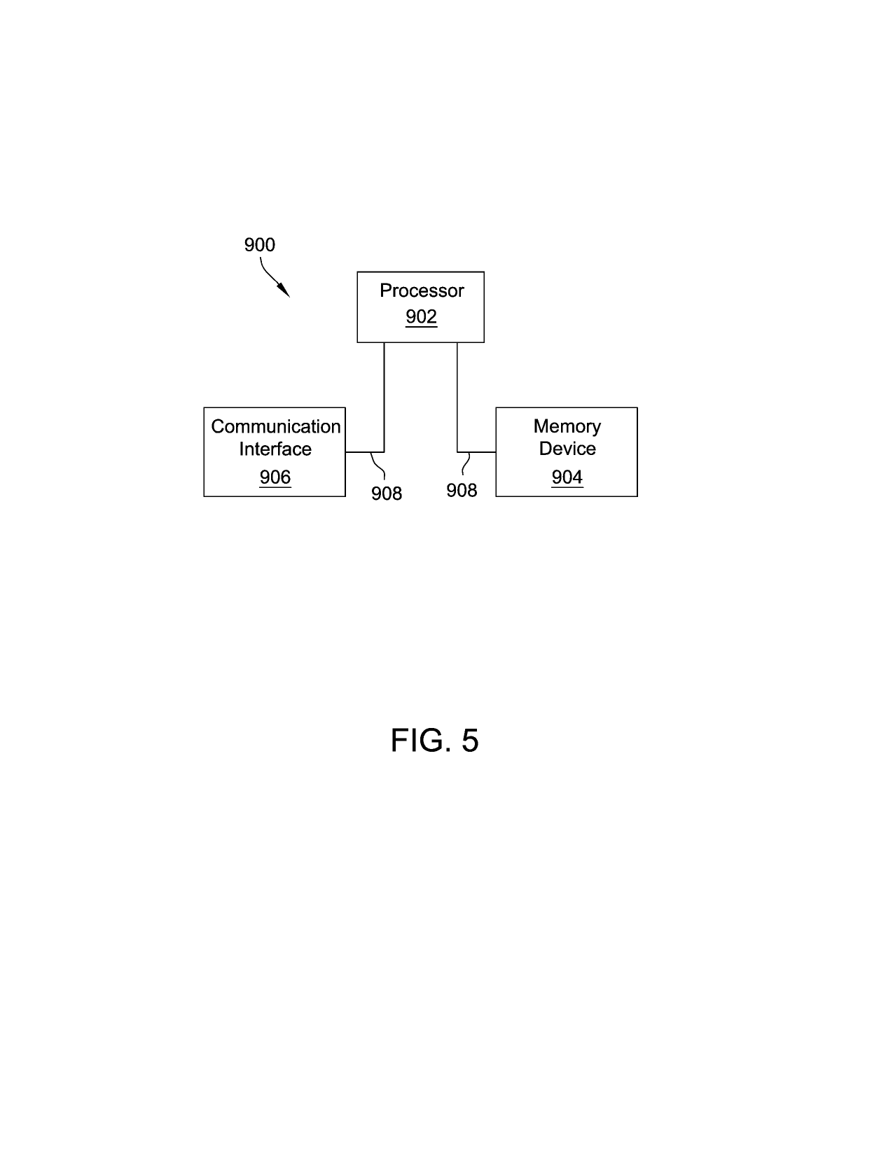

FIG. 5 is a block diagram of an example computing device 900. Computing device 900 includes a processor 902 and a memory device 904. The processor 902 is coupled to the memory device 904 via a system bus 908. The term “processor” refers generally to any programmable system including systems and microcontrollers, reduced instruction set computers (RISC), complex instruction set computers (CISC), application specific integrated circuits (ASIC), programmable logic circuits (PLC), and any other circuit or processor capable of executing the functions described herein. The above examples are example only, and thus are not intended to limit in any way the definition or meaning of the term “processor.”

In the example embodiment, the memory device 904 includes one or more devices that enable information, such as executable instructions or other data (e.g., sensor data), to be stored and retrieved. Moreover, the memory device 904 includes one or more computer readable media, such as, without limitation, dynamic random access memory (DRAM), static random access memory (SRAM), a solid state disk, or a hard disk. In the example embodiment, the memory device 904 stores, without limitation, application source code, application object code, configuration data, additional input events, application states, assertion statements, validation results, or any other type of data. The computing device 900, in the example embodiment, may also include a communication interface 906 that is coupled to the processor 902 via system bus 908. Moreover, the communication interface 906 is communicatively coupled to data acquisition devices.

In the example embodiment, processor 902 may be programmed by encoding an operation using one or more executable instructions and providing the executable instructions in the memory device 904. In the example embodiment, the processor 902 is programmed to select a plurality of measurements that are received from data acquisition devices.

In operation, a computer executes computer-executable instructions embodied in one or more computer-executable components stored on one or more computer-readable media to implement aspects of the disclosure described or illustrated herein. The order of execution or performance of the operations in embodiments of the disclosure illustrated and described herein is not essential, unless otherwise specified. That is, the operations may be performed in any order, unless otherwise specified, and embodiments of the disclosure may include additional or fewer operations than those disclosed herein. For example, it is contemplated that executing or performing a particular operation before, contemporaneously with, or after another operation is within the scope of aspects of the disclosure.

An example technical effect of the methods, systems, and apparatus described herein includes at least one of: (a) increasing capacity of cooling systems to manage heat generated by vehicles; (b) providing cooling systems to facilitate safe operation of a vehicle if one or more systems are in a failure state; (c) increasing the reliability of vehicles and systems for cooling vehicles; (d) increasing the cooling efficiency of systems for cooling vehicles, and (e) reducing the risk of overheating of an autonomy computing system.

Some embodiments involve the use of one or more electronic processing or computing devices. As used herein, the terms “processor” and “computer” and related terms, e.g., “processing device,” and “computing device” are not limited to just those integrated circuits referred to in the art as a computer, but broadly refers to a processor, a processing device or system, a general purpose central processing unit (CPU), a graphics processing unit (GPU), a microcontroller, a microcomputer, a programmable logic controller (PLC), a reduced instruction set computer (RISC) processor, a field programmable gate array (FPGA), a digital signal processor (DSP), an application specific integrated circuit (ASIC), and other programmable circuits or processing devices capable of executing the functions described herein, and these terms are used interchangeably herein. These processing devices are generally “configured” to execute functions by programming or being programmed, or by the provisioning of instructions for execution. The above examples are not intended to limit in any way the definition or meaning of the terms processor, processing device, and related terms.

The various aspects illustrated by logical blocks, modules, circuits, processes, algorithms, and algorithm steps described above may be implemented as electronic hardware, software, or combinations of both. Certain disclosed components, blocks, modules, circuits, and steps are described in terms of their functionality, illustrating the interchangeability of their implementation in electronic hardware or software. The implementation of such functionality varies among different applications given varying system architectures and design constraints. Although such implementations may vary from application to application, they do not constitute a departure from the scope of this disclosure.

Aspects of embodiments implemented in software may be implemented in program code, application software, application programming interfaces (APIs), firmware, middleware, microcode, hardware description languages (HDLs), or any combination thereof. A code segment or machine-executable instruction may represent a procedure, a function, a subprogram, a routine, a subroutine, a module, a software package, a class, or any combination of instructions, data structures, or program statements. A code segment may be coupled to, or integrated with, another code segment or an electronic hardware by passing or receiving information, data, arguments, parameters, memory contents, or memory locations. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the disclosed functions may be embodied, or stored, as one or more instructions or code on or in memory. In the embodiments described herein, memory includes non-transitory computer-readable media, which may include, but is not limited to, media such as flash memory, a random access memory (RAM), read-only memory (ROM), erasable programmable read-only memory (EPROM), electrically erasable programmable read-only memory (EEPROM), and non-volatile RAM (NVRAM). As used herein, the term “non-transitory computer-readable media” is intended to be representative of any tangible, computer-readable media, including, without limitation, non-transitory computer storage devices, including, without limitation, volatile and non-volatile media, and removable and non-removable media such as a firmware, physical and virtual storage, CD-ROM, DVD, and any other digital source such as a network, a server, cloud system, or the Internet, as well as yet to be developed digital means, with the sole exception being a transitory propagating signal. The methods described herein may be embodied as executable instructions, e.g., “software” and “firmware,” in a non-transitory computer-readable medium. As used herein, the terms “software” and “firmware” are interchangeable and include any computer program stored in memory for execution by personal computers, workstations, clients, and servers. Such instructions, when executed by a processor, configure the processor to perform at least a portion of the disclosed methods.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary” or “example” embodiment are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

What is claimed is:

1. A method for cooling an autonomy computing system of a vehicle, the method comprising:
receiving, at a controller, information relating to at least one of an environmental condition or an operating state of the vehicle;
determining a predicted computing load of the autonomy computing system of the vehicle based on the received information, the autonomy computing system including at least one set of electronic control units (ECUs) that are configured to operate the vehicle;
determining a predicted heat load generated by the autonomy computing system based on the predicted computing load of the autonomy computing system;
determining an operating parameter of a cooling system based on the predicted heat load, the cooling system including at least one fluid line defining a fluid passageway in thermal communication with the autonomy computing system of the vehicle; and
operating the cooling system based on the determined operating parameter to direct fluid through the fluid passageway and remove heat generated by the at least one set of ECUs.

2. The method of claim 1, wherein the information relating to at least one of the environmental condition or the operating state of the vehicle includes a temperature of an ambient environment around the vehicle or a temperature associated with the at least one set of ECUs.

3. The method of claim 1, wherein the information relating to at least one of the environmental condition or the operating state of the vehicle includes a traffic pattern associated with a location and predicted path of the vehicle.

4. The method of claim 1, further comprising operating a valve coupled to the at least one fluid line to selectively direct the fluid in the fluid passageway toward at least one ECU of the at least one set of ECUs based on the determined operating parameter.

5. The method of claim 1, wherein the at least one set of ECUs includes a first set of ECUs and a second set of ECUs, wherein the at least one fluid line includes a first fluid line defining a first fluid passageway in thermal communication with the first set of ECUs and a second fluid line defining a second fluid passageway in thermal communication with the second set of ECUs, and wherein the cooling system is operated to provide independent cooling to the first set of ECUs and the second set of ECUs.

6. The method of claim 5, further comprising:
determining a failure state of a first ECU of the first set of ECUs; and
identifying a second ECU of the second set of ECUs that performs a function that corresponds to a function of the first ECU, wherein the autonomy computing system is operated to accommodate the failure state of the first ECU by relying on the functions of the second ECU.

7. The method of claim 5, wherein operating the cooling system based on the determined operating parameter to direct the fluid through the fluid passageway comprises operating the cooling system based on the determined operating parameter to selectively direct the fluid through the first fluid passageway and toward each ECU of the first set of ECUs.

8. The method of claim 1, further comprising:
determining an amount of the predicted heat load that is associated with an ECU of the at least one set of ECUs; and
operating the cooling system to direct fluid to the ECU and provide cooling for the predicted heat load that is associated with the ECU.

9. A system for cooling a vehicle, the system comprising:
at least one fluid line defining a fluid passageway in thermal communication with at least one set of electronic control units (ECUs) of an autonomy computing system of the vehicle, wherein the autonomy computing system is configured to operate the vehicle;
at least one heat exchanger connected to the at least one fluid line; and
a controller configured to:
receive information relating to at least one of an environmental condition or an operating state of the vehicle;
determine a predicted computing load of the autonomy computing system of the vehicle based on the received information;
determine a predicted heat load generated by the autonomy computing system based on the predicted computing load of the autonomy computing system;
determine an operating parameter of the system based on the predicted heat load; and
operate the system based on the determined operating parameter to direct fluid through the fluid passageway and remove heat generated by the at least one set of ECUs.

10. The system of claim 9, wherein the information relating to at least one of the environmental condition or the operating state of the vehicle includes a temperature of an ambient environment around the vehicle or a temperature associated with the at least one set of ECUs.

11. The system of claim 9, wherein the information relating to at least one of the environmental condition or the operating state of the vehicle includes a traffic pattern associated with a location and predicted path of the vehicle.

12. The system of claim 9, further comprising a valve coupled to the at least one fluid line and operable to selectively direct the fluid in the fluid passageway toward at least one ECU of the at least one set of ECUs based on the determined operating parameter.

13. The system of claim 9, wherein the at least one set of ECUs includes a first set of ECUs and a second set of ECUs, wherein the at least one fluid line includes a first fluid line defining a first fluid passageway in thermal communication with the first set of ECUs and a second fluid line defining a second fluid passageway in thermal communication with the second set of ECUs, and wherein the system is operated to provide independent cooling to the first set of ECUs and the second set of ECUs.

14. The system of claim 13, wherein the controller is configured to:
determine a failure state of a first ECU of the first set of ECUs; and
identify a second ECU of the second set of ECUs that performs a function that corresponds to a function of the first ECU, wherein the autonomy computing system is operated to accommodate the failure state of the first ECU by relying on the functions of the second ECU when the vehicle performs the emergency maneuver or continues operation.

15. The system of claim 9, wherein the controller is configured to:
determine an amount of the predicted computing load that is associated with the at least one set of ECUs; and
operate the system to provide cooling to account for the predicted computing load that is associated with the at least one set of ECUs.

16. A vehicle comprising:
an autonomy computing system including at least one set of electronic control units (ECUs);
at least one sensor communicatively coupled to the at least one set of ECUs, wherein the at least one set of ECUs is configured to process information provided by the at least one sensor and operate the vehicle;
a cooling system including at least one fluid line in thermal communication with the autonomy computing system and defining a fluid passageway for fluid to receive heat generated by the autonomy computing system; and
a controller configured to:
receive information relating to at least one of an environmental condition or an operating state of the vehicle;
determine a predicted computing load of the autonomy computing system of the vehicle based on the received information;
determine a predicted heat load generated by the autonomy computing system based on the predicted computing load of the autonomy computing system;
determine an operating parameter of the cooling system based on the predicted heat load; and
operate the cooling system based on the determined operating parameter to direct fluid through the fluid passageway and remove heat generated by the autonomy computing system.

17. The vehicle of claim 16, wherein the at least one sensor includes a temperature sensor, and wherein the information relating to at least one of the environmental condition or the operating state of the vehicle includes at least one of a temperature of an ambient environment around the vehicle, or a temperature associated with the at least one set of ECUs.

18. The vehicle of claim 16, wherein the at least one sensor includes an environmental sensor, and wherein the information relating to at least one of the environmental condition or the operating state of the vehicle includes at least one of a weather condition or a traffic pattern associated with a location and predicted path of the vehicle.

19. The vehicle of claim 17, wherein the at least one set of ECUs includes a first set of ECUs and a second set of ECUs, wherein the at least one fluid line includes a first fluid line defining a first fluid passageway in thermal communication with the first set of ECUs and a second fluid line defining a second fluid passageway in thermal communication with the second set of ECUs, and wherein the cooling system is operated to provide independent cooling to the first set of ECUs and the second set of ECUs.

20. The vehicle of claim 17, wherein the controller is configured to:
determine a failure state of a first ECU of the at least one set of ECUs; and
identify a second ECU of the at least one set of ECUs that performs a function that corresponds to a function of the first ECU, wherein the autonomy computing system is operated to accommodate the failure state of the first ECU by relying on the functions of the second ECU when the vehicle performs the emergency maneuver or continues operation.
